(19) United States
(12) Patent Application Publication
(10) Pub. No.: US 2001/0036728 A1
(43) Pub. Date: Nov. 1, 2001

(54) Method of manufacturing semiconductor device

(75) Inventors: Toshiki Shinmura, Tokyo (JP); Makoto matsuo, Tokyo (JP); Eiichi Soda, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/838,106

(22) Filed: Apr. 19, 2001

(30) Foreign Application Priority Data
Apr. 19, 2000 (JP) 118273/2000

(51) Int. Cl. H01L 21/44

(52) U.S. Cl. 438/660

(57) ABSTRACT

In the formation of the wiring as a gate electrode of a polycide structure or a polymetal structure using a high melting-point metal, sharp recesses 24 on the surface of a polycrystalline silicon film 6 in the area situated the concave portions 4 generated at the ends of a trench element-isolating insulator 3 are removed. Thereafter an amorphous high melting-point metal silicide film or an amorphous high melting-point metal film via a nitride film of a high melting-point metal is formed on the flattened silicon film. Then, the amorphous high melting-point metal film or the like is crystallized to form a crystallized high melting-point metal film or the like. The polycrystalline silicon film 6a and the high melting-point metal silicide film 8 or the like are patterned to form the gate electrode of an MOS transistor. According to the manufacturing method, the occurrence of cracks in the high melting-point metal film or the high melting-point metal silicide film on a silicon film can be suppressed.

### BACKGROUND OF THE INVENTION

1. Field of the Invention

The present invention relates to a method of manufacturing a semiconductor device and in particular to a wiring formation method using high melting-point metals or silicide films.

2. Description of the Related Art

Intensive efforts are still paid for miniaturization and high density structure of a semiconductor element such as insulated gate field effect transistor (hereinafter, referred to as MOS transistor) or the like. With respect to the miniaturization, a MOS transistor formed in 0.10 to 0.13 μm dimension is used at present. A semiconductor device such as a memory device or a logic device with this dimension employed as the design standard has been developed.

Such miniaturization is the most effective approach for high performance or multiple function due to a high integration, a speedup or the like of a semiconductor device. Among such higher integration, speedup, function multiplexing and further lower power consumption of a semiconductor device, the formation of wiring such as gate electrode becomes important.

For the gate electrode of an MOS transistor, for example, a polycide film as constitution of high melting-point metal silicide layer/polysilicon (polycrystalline silicon) layer is used and further at present a polymetal film as constitution of a high melting-point metal layer/polysilicon layer has become indispensable.

Among such needs, not only miniaturization of wiring but lower resistance thereof is also necessary. Also, a variety of examinations have been made of flattening an underlying layer for the wiring. Here, with the miniaturization of a semiconductor element, use of a trench element has become general, but a concave portion generated in the trench separating area is inevitable under present-day circumstances. Namely, flattening in the trench separating area is difficult at present.

Such being the case, referring to FIG. 1, a description will be made of a case of the prior art where a gate electrode of a polycide structure is formed on the trench separating area as mentioned above. FIG. 1 is a sectional view of the step procedure in the case of forming a titanium polycide film.

As shown in FIG. 1A, a trench 102 is formed at a predetermined area on the silicon substrate 101 by using the well-known photolithography and dry etching techniques. After the formation of a silicon oxide film over the entire surface of a silicon substrate 101 by the CVD (Chemical Vapor Deposition) process, the silicon oxide film on the major surface of the silicon substrate 101 is polished and removed by the CMP (Chemical Mechanical Polishing) Process. In this manner, an element-isolating insulator 103 is embedded into the trench 102.

As shown in FIG. 1A, however, a concave portion 104 is inevitably formed at the end of the element-isolating insulator 103 in the trench 102. Generation of this concave portion 104 is caused by necessity because a hydrofluoric acid treatment step is essential to the formation of the above element-isolating insulator and the end of the element-isolating insulator 103 in the trench 102 is etched with a hydrofluoric acid.

Next, on the major surface of the silicon substrate 101, a gate insulating film 105 for the MOS transistor is formed.

Next, as shown in FIG. 1B, a polycrystalline silicon film 106 on the order of 100 nm thickness is deposited by the well-known reduced-pressure CVD process. With this CVD, a phosphorus impurity is doped to the polycrystalline silicon film 106 in-situ. During this film formation on the concave portion 103 formed at the element-isolating insulator 103 in the trench 102, a cusp-shaped sharp recess 107 is formed on the surface of the polycrystalline silicon film 106.

Next, as shown in FIG. 1C, over the entire surface of the above polycrystalline silicon film 106, a titanium silicide film 108 is deposited by the sputtering process. Here, the thickness of the titanium silicide film 108 is on the order of 200 nm. Incidentally, the substrate temperature during the sputtering ranges from 100° C. to 200° C. and the deposited titanium silicide film 108 is of an amorphous structure.

Furthermore, the RTA (Rapid Thermal Annealing: rapid thermal treatment) is applied to this sputtering-formed titanium silicide film 108. Namely, the titanium silicide film is crystallized by the RTA at a temperature of the order of 850° C. This treatment leads to a titanium silicide of low-resistance C54 structure from amorphous state through a titanium silicide film of C49 structure. In this manner, the titanium silicide film 108 becomes low in resistance, but occurrence of cracks 109 as shown in FIG. 1C accompanies.

The subsequent steps will not be illustrated, but the above polycrystalline silicon film 106 and the above titanium silicide film 108 are minutely treated the publicly known photo-lithography and dry etching techniques, thus results in formation of the gate electrode of an MOS transistor.

According to the prior art, however, as mentioned above, cracks 109 are generated on the silicide film in the policide-film formation of a high-melting metal such as titanium. Applied to this phenomenon were various examinations and experiments by the present inventors. This crack occurrence will be described referring to FIG. 2. FIG. 2 is a schematically sectional view of the above polycide film.

On the surface of an underlayer material 110 (corresponding to the above element-insulator in the trench), a concave portion 111 is formed. And, on such an underlayer material 110, a polycrystalline silicon film 112 and an amorphous silicide film 113 are stacked and formed. Here, a cusp-shaped sharp recess 114 is formed at a place situated above the concave portion 111 of the underlayer material 110.

In the step of applying a thermal treatment such as RTA to reduce the resistance of this silicide film 113, cracks 115 are generated on the above silicide film 113. In case of the above titanium silicide 113, for example, titanium silicide is contracted in volume by several % during the phase transition from the amorphous structure to C49-structured polycrystals. And, the volume is contracted by approx. 5% during the phase transition from this C49-structured to C54-structured polycrystals. In a crystallizing step of such an amorphous titanium silicide film, a tensile stress comes to be imposed on the titanium silicide film and consequently the above cracks 115 are generated.

Occurrence of such cracks 115 greatly depends on the surface structure of a polycrystalline silicon film serving for the underlayer. From detailed examinations and experiments, the present inventor ascertained that cracks were generated at a place where a cusp-shaped sharp recess was formed as shown in FIG. 2. Such cracks will be generated even on a polymetal film but not only for a polycide film under certain conditions.

When such crack occurrence as mentioned above occurs, the wiring resistance of a gate electrode or the like increases and performances of a semiconductor device lowers. Or else, rejects appear, thereby resulting in a great decrease in the manufacturing yield of semiconductor devices.

### SUMMARY OF THE INVENTION

Accordingly, it is one object of the present invention not only to solve such a problem as mentioned above by a simple and convenient method but to provide a method capable of forming such wiring as mentioned above at high precision under high reliability also.

According to a first feature of the present invention, there is provided a method of manufacturing a semiconductor device for forming a wiring layer of the semiconductor device, which method comprises the steps of forming a silicon film on a surface of an underlying insulating layer having a concave portion and flattening a surface of a high melting-point metal silicide film by a flattening treatment. Thereafter, forming a high melting-point metal silicide film of amorphous state or forming a high melting-point metal film of amorphous via a nitride film of a high melting-point metal on the flattened surface of the silicon film. Thereafter, crystallizing the high melting-point metal silicide film or the high melting-point metal film by a heat treatment.

In the first feature of the present invention, the flattening treatment may be a CMP (chemical mechanical polishing) treatment applied to the surface of said silicon film. Or else, the flattening treatment may be a reactive ion etching treatment removing a predetermined depth of the surface of a said silicon film. Or else, the flattening treatment may includes a first step of forming a thermal oxide film on the surface on the silicon surface by thermal oxidizing, preferably, by a rapid thermal oxidizing, and removing the thermal oxide film. Or else, the thermal oxidizing may be a heat treatment under a mixing gas atmosphere of chloride of phosphoric acid (POCl₃) and oxygen (O₂).

Further in the first feature of the present invention, the silicon film may be polycrystalline silicon film or an amorphous silicon film. In this case, an impurity to determine N type or P type may be introduced into said silicon film when the silicon film is deposited on the surface of the underlying insulating layer. Preferably, the melting-point metal silicide film is a titanium silicide film, a tungsten silicide film or cobalt silicide film. And, preferably, the high melting-point metal film is a titanium film, a tungsten film or cobalt film. Moreover, after crystallizing the high melting-point metal silicide film or the high melting-point metal film, the method of the first feature may further comprise a step of patterning the high melting-point metal silicide film and the silicon film or patterning the high melting-point metal film, the nitride film of the high melting-point metal and the silicon film to form a gate electrode wiring of a MOS transistor. Moreover, the underlying insulating layer having concave portion is an element-isolating layer defining an element-forming region in which a MOS transistor may be formed.

According to a second feature of the present invention, there is provided a method of manufacturing a semiconductor device, which method comprises the steps of forming a silicon film on a surface of an underlying insulating layer having a concave portion and forming a high melting-point metal silicide film of amorphous state or forming a high melting-point metal film of amorphous via a nitride film of a high melting-point metal on a surface of the silicon film. Thereafter, crystallizing the high melting-point metal silicide film or the high melting-point metal film by a heat treatment.

In the second feature of the present invention, the silicon film may a polycrystalline silicon film or an amorphous silicon film. In this case, an impurity to determine N type or P type may be introduced into said silicon film when the silicon film is deposited on the surface of said underlying insulating layer. Further, preferably, the melting-point metal silicide film is a titanium silicide film, a tungsten silicide film or cobalt silicide film. And, preferably, the melting-point metal film is a titanium film, a tungsten film or cobalt film.

As the first feature, in the second feature also, after crystallizing the high melting-point metal silicide film or the high melting-point metal film, the method may further comprises a step of patterning the high melting-point metal silicide film and the silicon film or patterning the high melting-point metal film, the nitride film of the high melting-point metal and the silicon film to form a gate electrode wiring of a MOS transistor. Further, the underlying insulating layer having concave portion may be an element-isolating layer defining an element-forming region in which a MOS transistor is formed.

As mentioned above, the present inventor ascertained that cracks generated during the thermal treatment of the multi-layer film comprising a silicon film and a high melting-point metal silicide film or a multilayer film comprising the silicon film and a high melting-point metal film via nitride film of a high melting-point metal greatly depends on the surface structure serving for the underlayer. Here, the silicon film means a polycrystalline silicon film or an amorphous silicon film. This is a new finding that has never been obtained till by the present inventor.

The present invention, based on the above new finding, is characterized in that a sharp recess (e.g. cusp-shaped recess) on the surface of a silicon film is moderated in gradient and removed, then the above amorphous high melting-point metal silicide film is formed and this amorphous high-melting metal silicide film is crystallized. By removing such a sharp recess, the concentration of a tensile stress imposed on the high-melting metal silicide film at the recess portion during thermally treatment for crystallization is mitigated and occurrence of cracks as mentioned above is suppressed.

### BRIEF DESCRIPTION OF THE DRAWINGS

This above-mentioned and other objects, features and advantages of this invention will become more apparent by reference to the following detailed description of the invention taken in conjunction with the accompanying drawings, wherein:

FIG. 1A to FIG. 1C are cross sectional views showing the manufacturing procedure of a polycide structure according to the related art;

FIG. 2 is a schematically cross sectional view showing the problems in the related art;

FIG. 3A to FIG. 3E are cross sectional views showing the manufacturing procedure of a polycide structure according to First Embodiment of the present invention;

FIG. 4A is a plan view showing the procedure subsequent to the FIG. 3E, and FIG. 4B and FIG. 4C are cross sectional views taken along lines B-B and C-C in FIG. 4A and view as indicated in arrows, respectively;

FIG. 5 is a cross sectional view of the constitution of a sputter device for a titanium silicide film;

FIG. 6A to FIG. 6C are cross sectional views showing the manufacturing procedure of a polycide structure according to Second Embodiment of the present invention;

FIG. 7A to FIG. 7C are cross sectional views showing the manufacturing procedure of a polycide structure according to Third Embodiment of the present invention; and

FIG. 8A to FIG. 8C are cross sectional views showing the manufacturing procedure of a polycide structure according to Fourth Embodiment of the present invention.

### DETAILED DESCRIPTION OF THE PREFERRED EMBODIMENTS

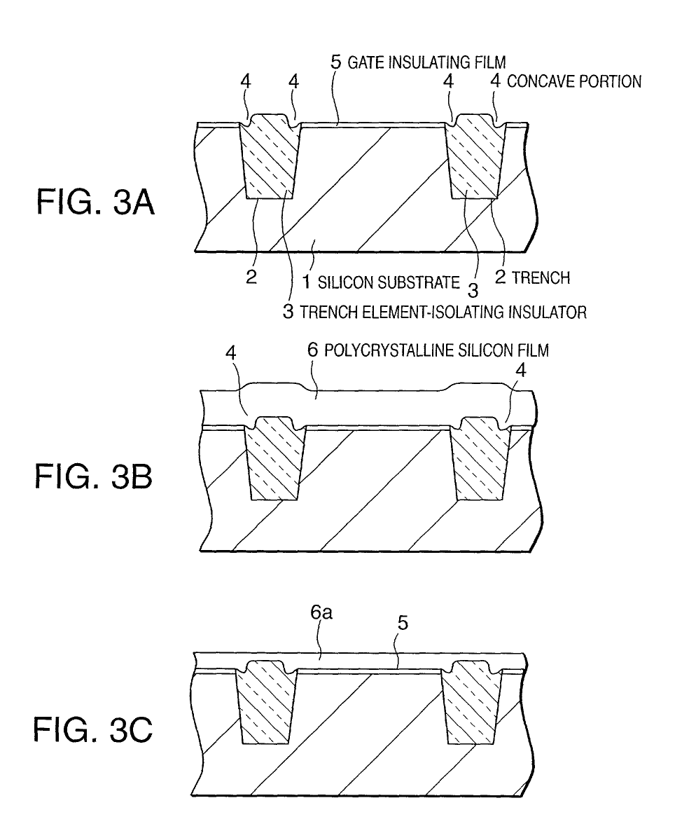

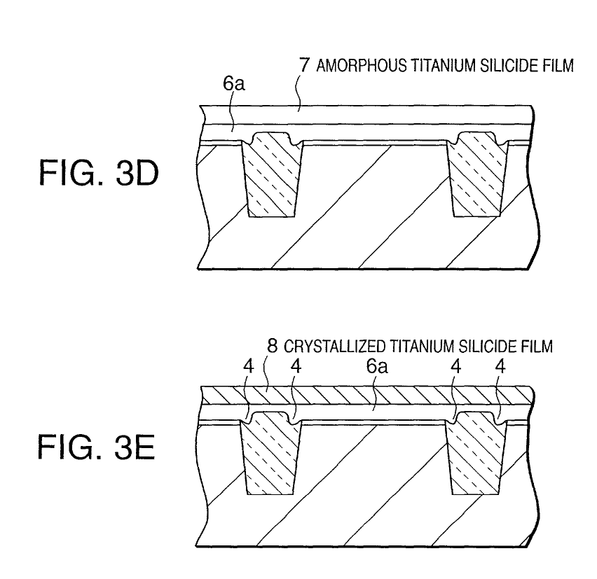

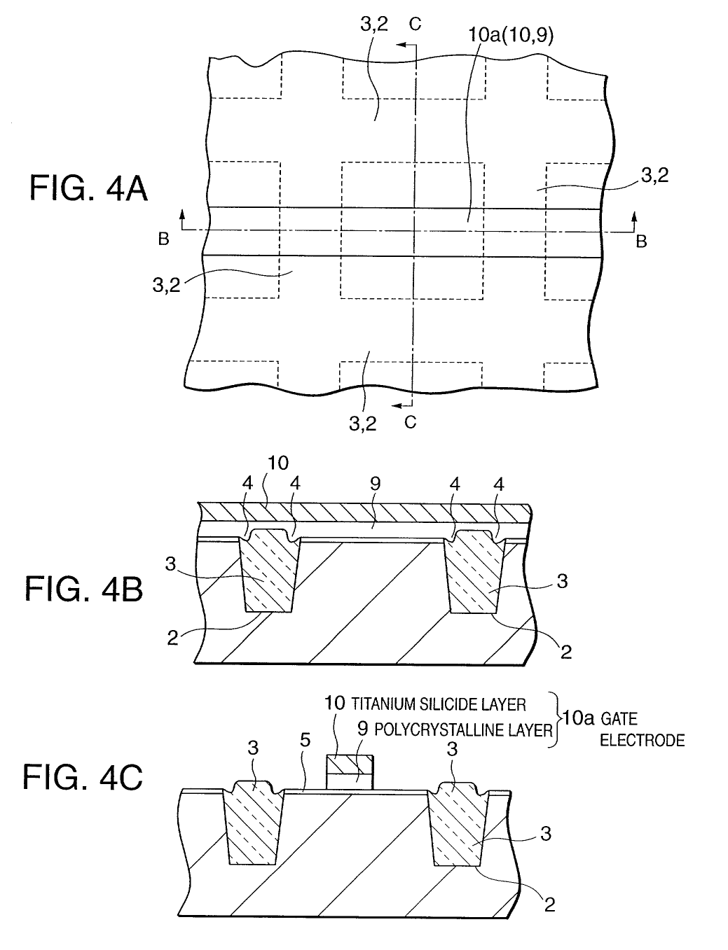

Now, referring to FIG. 3A to FIG. 3E and FIG. 4A to FIG. 4C, First Embodiment of the present invention will be described. These figures show the manufacturing procedure in case of forming the gate electrode of an MOS transistor enclosed with a trench element-isolating area.

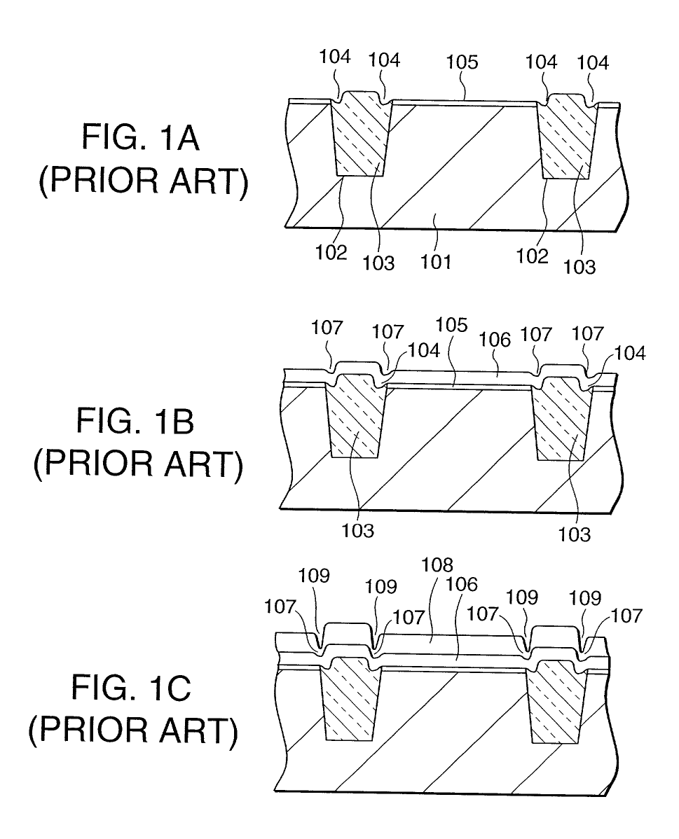

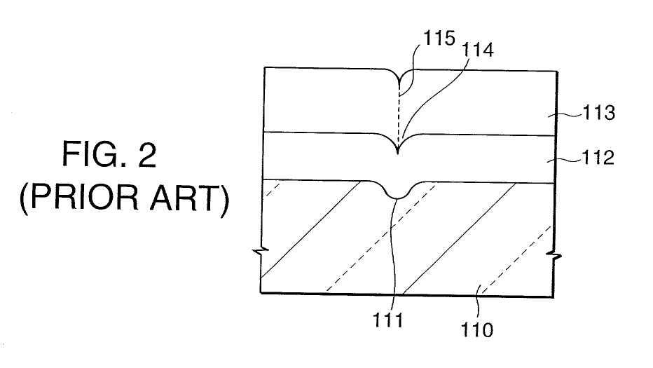

At first, as shown in FIG. 1A, as described in the section of the Description of the Related Art, a trench 2 is formed at a predetermined area on the silicon substrate 1. Thereafter, after depositing a silicon oxide film entirely by the CVD, the silicon oxide film on the major surface of the silicon substrate 1 is polished and removed by and the CMP of the silicon oxide film. In this manner, the trench element-isolating insulator 3 is embedded in the trench 2.

Here, as with the related art, a concave portion 4 is formed on the end of the trench element-isolating insulator 3 by the manufacturing step. Next, on the major surface of the silicon substrate 1, a gate insulating film 5 in use for the MOS transistor is formed by the thermal oxidation and/or nitridation of the silicon substrate.

Next, as shown in FIG. 3B, a phosphorus-doped polycrystalline silicon film 6 is deposited to a thickness of the order of 300 nm by the known reduced-pressure CVD process. Here, the thickness of the polycrystalline silicon film 6 is set enough for the above concave portion 4 to be embedded completely.

Next, as shown in FIG. 3C, the polycrystalline silicon film 6 is polished by the CMP process. In this manner, a polycrystalline silicon film 6a with a completely smoothed surface is formed. Here, this smoothed polycrystalline silicon film 6a becomes on the order of 100 nm in thickness on the gate insulating film 5.

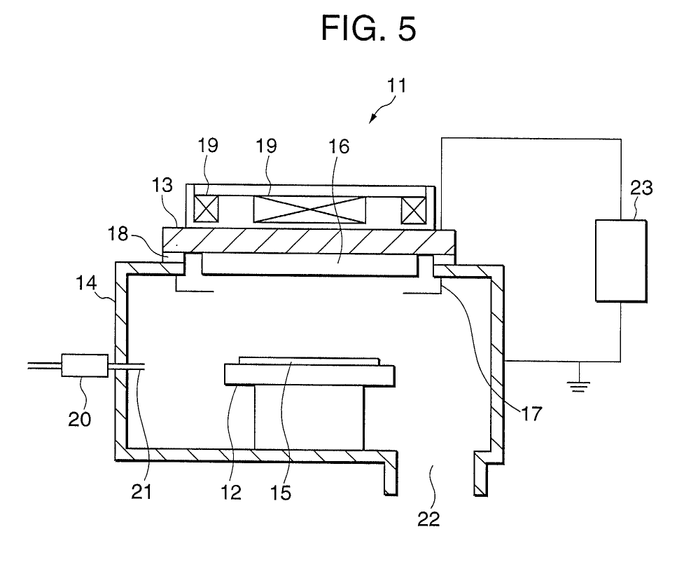

Next, as shown in FIG. 3D, over entire surface of the above polycrystalline silicon film 6a, an amorphous titanium silicide film 7 is deposited by sputtering. This sputtering process will be described below by referring to FIG. 5. Here, the thickness of the amorphous titanium silicide film 7 ranges from 100 nm to 200 nm. Using the sputtering device 11 described later, an amorphous titanium silicide film 7 is deposited on the flattened polycrystalline silicon film 6a with an alloy of Ti—Si composition ratio of Ti:Si=1:2.4 employed as the sputter target. Incidentally, the composition of the amorphous titanium silicide film 7 to be sputtered is equal to that of the sputter target and has a Ti/Si ratio of 1 to 2.4.

As shown in FIG. 5, the sputter device 11 used in the film forming step of the above titanium silicide film is equipped with a sputter chamber 14 comprising a substrate holder 12 at the bottom and a backing plate 13 as the target holder at the top opening part. Here, the substrate holder 12 has a semiconductor wafer 15 on which to deposit a titanium silicide film placed on it.

The backing plate 13 holds a target 16 at the center. Around the backing plate 13, a protective attachment shield 17 is provided so as to prevent sputter particles from being sputtered to the lateral wall of the sputter chamber 14. The packing plate 13 is electrically insulated from the sputter chamber 14 by the insulator 18 and is equipped with a magnet 19 at the top.

Furthermore, a mass flow controller 20 is provided, and a gas supply tube 21 for supplying a sputter gas to the sputter chamber 14 is connected to the sputter chamber 14. Moreover, the exhaust port 22 for exhausting the interior of the sputter chamber 14 is provided at the bottom of the sputter chamber 14 and is connected to a vacuum suction device (not shown).

Furthermore, the sputter device 11 is equipped with a sputter power supply 23 for applying a voltage between the backing plate 13 and the sputter chamber 14.

Since the presence of oxygen in the sputter chamber 14 during the sputtering unfavorably affects the deposit film formed by the sputtering, the interior of the sputter chamber 14 is filled with an inert gas to maintain a pressure of 1×10⁻⁵ Pa or lower while the sputtering device 11 is not running.

During the sputtering, a voltage is applied to induce a glow discharge inside the sputter chamber 14 with Ar employed for the sputter gas, the pressure of Ar gas set to approx. 1.1 Pa and the output of the power supply set to 5 kW. Here, the wafer 15 is so controlled in temperature as to keep its temperature on the order of 150° C.

Next, this sputtering-formed amorphous titanium silicide film 7 is subjected to the RTA. Namely, by the RTA of the order of 850° C., a titanium silicide film is crystallized. With this treatment, a structural change of the titanium silicide film advances through C49 structure to low resistance C 54 structure. In this manner, a crystallized titanium silicide film 8 is formed on the polycrystalline silicon film 6a as shown in FIG. 3E. The crystallization in this step is originated from the reduction in the resistance of the titanium silicide film. This procedure is because crystallizing after the patterning as the gate electrode stated later raises the sheet resistance of the gate electrode processed into a fine pattern due to the fine line effect.

According to the present invention, since the surface of the polycrystalline silicon film 6 is flattened, a cusp-shaped recess described in Description of the Related Art is eliminated. As a result, no crack whatever occurs in all areas including that of concave portions 4 during the crystallizing step of the titanium silicide film.

Subsequently, as shown in FIG. 4, the crystallized titanium silicide film 8 and the polycrystalline silicon film 6a are patterned to form a polycide structure of the gate wiring electrode 10a composed of a titanium silicide layer 10 and a polycrystalline silicon layer 9.

In the FIG. 4, FIG. 4A is a plan view showing the procedure subsequent to the FIG. 3E, FIG. 4B is a cross sectional view taken along line B-B in FIG. 4A and views as indicated in arrows, and FIG. 4C is a cross sectional view taken along line C-C in FIG. 4A and views as indicated in arrows.

In this manner, a gate electrode 10a is formed under a high reliability on the gate insulating film 5 of an MOS transistor enclosed with the trench element-isolating insulator 3.

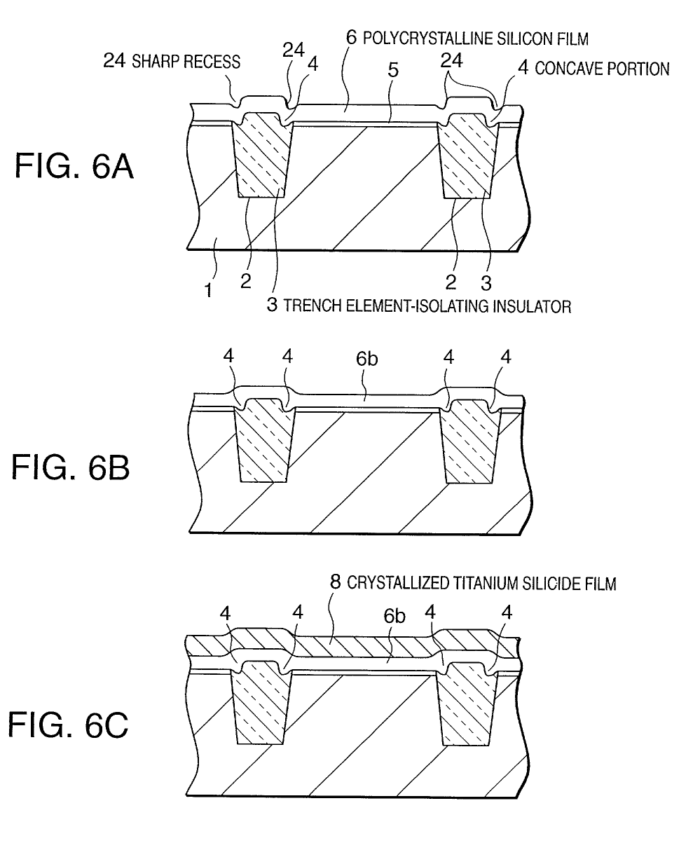

Next, referring to FIG. 6A to FIG. 6C, Second Embodiment of the present invention will be described below. FIG. 6A to FIG. 6C are cross sectional views of the manufacturing procedure of forming a polycide structure according to the present invention. Unlike First Embodiment, this case is characterized by removing a sharp recess on a polycrystalline silicon film, but not by completely smoothing the surface of the polycrystalline silicon film. Here, parts similar to those of First Embodiment is identified by the same reference symbols.

At first, as shown in FIG. 6A, a trench 2 is formed at a predetermined area on the silicon substrate 1 to embed a trench element-isolating insulator 3 in the trench 2. Here, at the manufacturing step, a concave portion 4 is formed at the end of the trench element-isolating insulator 3. Furthermore, on the major surface of the silicon substrate 1, a gate insulating film 5 in use for the MOS transistor is formed. Further, a phosphorus-doped polycrystalline silicon film 6 is deposited to a thickness of the order of 200 nm by the reduced-pressure CVD process. Here, a sharp recess 24 is formed on the surface of the polycrystalline silicon film 6 in the area of the above concave portion 4.

Next, as shown in FIG. 6B, to the surface of the above polycrystalline silicon film 6, etching back is applied. Here, this etching back is carried out by the anisotropic reactive ion etching (RIE) using a gas mixture of HBr and Cl₂. During this etching back step, the upper surface of the polycrystalline silicon film 6 is etched on the order of 100 nm and the above sharp recess 24 disappears. In this manner, a polycrystalline silicon film 6b free of any sharp recess is formed.

Subsequently, as shown in FIG. 6C, a crystallized titanium silicide is formed on the above polycrystal silicon film 6b as with the description related to First Embodiment.

Also with Second Embodiment, no crack whatever occurs in all areas including those of concave portions 4 during such a crystallizing step.

Though the subsequent steps are not illustrated, the above crystallized titanium silicide 8 and the polycrystalline silicon film 6b are patterned as the same manner shown in FIG. 4 of the First Embodiment. In this manner, the gate electrode of the MOS transistor becomes formable simply and conveniently under high reliability.

With Second Embodiment, the thickness of the polycrystalline silicon film 6 may be deposited thickly at the order of 300 nm in thickness as described in First Embodiment. If done thus, the above sharp recess is eliminated during this film-forming step. The etching back step of this case principally functions to thin the p polycrystalline silicon film. Needless to say, also in this case, etching back functions to further smooth the surface of the polycrystalline silicon film.

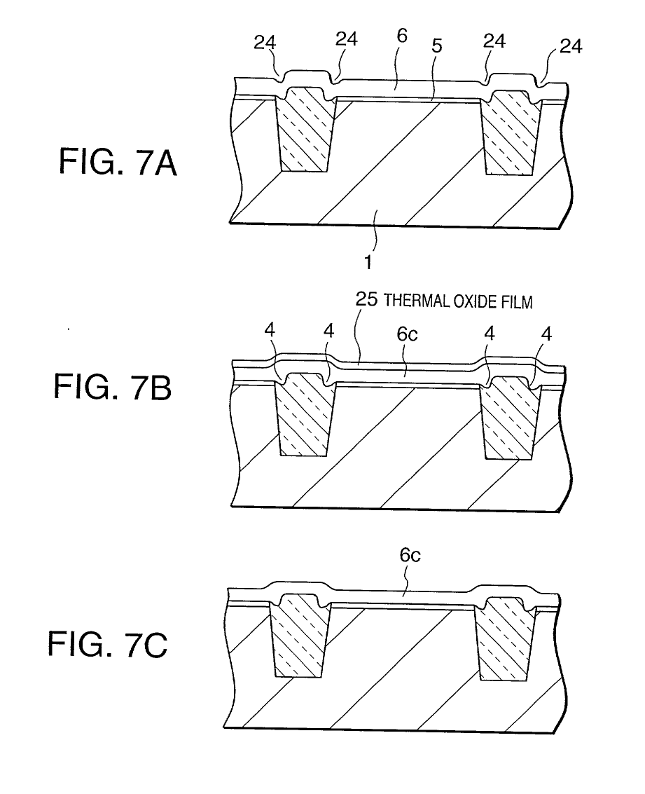

Next, Third Embodiment of the present invention will be described with referring to FIG. 7A to FIG. 7C. These figures are cross sectional views of the production procedure showing another method for eliminating a cusp-shaped sharp recess on the surface of the polycrystalline silicon film in forming a policide structure according to the present invention.

This case is characterized in that the surface of a polycrystal silicon film with cusp-shaped sharp recesses is thermally oxidized to eliminate the above sharp recesses. Here, parts similar to those of Second Embodiment are identified by the same reference symbols. Besides, the same description will be partly omitted.

As shown in FIG. 7A, a polycrystalline silicon film 6 is formed via a gate insulating film 5 on a silicon substrate 1. Here, the polycrystalline silicon film 6 comprises phosphorous-doped polycrystal silicon of the order of 150 nm in thickness. Also in this case, a cusp-shaped sharp recess 24 is formed on the surface of the polycrystalline silicon film 6.

Next, the surface of the above polycrystalline silicon film 6 is treated to rapid thermal oxidization (RTO). Here, the RTO treatment is carried out at high temperatures of the order of 1110° C. During this treatment, as shown in FIG. 7B, the surface of the polycrystalline silicon film 6 is thermally oxidized to form a thermal oxide film 25. By this high-temperature RTO treatment, the above sharp recess 24 disappears.

Then, the above thermal oxide film 25 is etching-removed using a hydrofluoric chemical. In this manner, a sharp-recess-free p polycrystalline silicon film 6c on the order of 100 nm in thickness is formed as shown in FIG. 7C.

Subsequently, as shown in FIG. 6C, a crystallized titanium silicide film is formed on this polycrystalline silicon film 6c. Also in Third Embodiment, since any sharp recess is removed on the surface of the polycrystalline film 6c as mentioned above, no crack whatever occurs in all areas including those of concave portions 4.

Such thermal oxidation of the surface of the polycrystalline silicon film as performed in Third Embodiment is performable even by another method. After depositing an undoped polycrystalline silicon film substantially not containing an impurity such as phosphorous on the order of 100 nm in thickness by the CVD method, for example, thermal treatment is performed in the gas mixture atmosphere of POCl₃ and O₂. Here, the thermal treatment is on the order of 800° C. By this thermal treatment, a phosphorous impurity is not only doped into the polycrystalline silicon film but a thermal oxide film is also formed on the surface thereof. Also in this case, the above-described sharp recess on the surface of the polycrystal silicon film disappears. Thereafter, the patterning process is performed to form the gate wiring as shown in FIG. 4 of the First Embodiment.

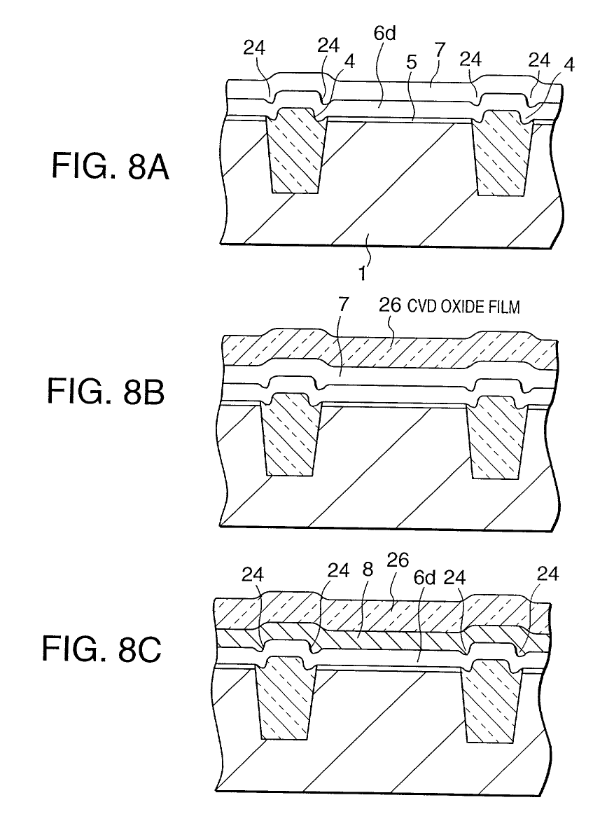

Next, Fourth Embodiment of the present invention will be described with referring to FIG. 8A to FIG. 8C. These figures are also cross sectional views of the manufacturing procedure for forming a polycide structure according to the present invention. This case is characterized in that after depositing an amorphous titanium silicide film on the polycrystalline silicon film having sharp recesses present on the surface thereof and further completely coating the surface of this titanium silicide film with an insulating film such as a silicon oxide film, the above amorphous titanium silicide film is subjected to thermal treatment. Here, parts similar to those of the above embodiments are identified by the same reference symbols. Besides, the same description will be partly omitted.

At first, as shown in FIG. 8A, a polycrystalline silicon film 6d is formed via a gate insulating film 5 on a silicon substrate 1. Here, the p polycrystalline silicon film 6d comprises phosphorous-doped polycrystalline silicon of the order of 100 nm in thickness. In this case, a cusp-shaped sharp recess 24 is formed on the surface of the polycrystalline silicon film 6d. Furthermore, on the polycrystalline silicon film 6d, an amorphous titanium silicide film 7 is deposited by the above sputter process.

Next, as shown in FIG. 8B, a CVD oxide film 26 is formed on the amorphous titanium silicide film 7. Here, the CVD oxide film 26 deposited by CVD is a silicon oxide film deposited to thickness of the order of 150 nm. The temperature of CVD in this case is on the order of 400° C. and it is necessary to completely prevent the amorphous titanium silicon film 7 from crystallizing.

Then, the amorphous titanium silicide film 7 covered with the CVD oxide film 26 is subjected to the RTA and made to crystallize, so that a titanium silicide film 8 crystallized into the C54 structure is formed as shown in FIG. 8C.

According to this method, a sharp recess 24 is present on the surface of the polycrystalline silicon film 6d. However, the above tensile stress mentioned in the Related Art is suppressed by the CVD oxide film 26 during the crystallizing step of the amorphous titanium silicide film 7 and therefore no crack what ever occurs in all areas including those of concave portions 4. Incidentally, if there is such an insulating film as suppresses the above tensile stress besides the CVD oxide film, a similar effect takes place. Thereafter, the patterning process is performed to form the gate wiring as shown in FIG. 4 of the First Embodiment.

In these embodiments, a description was made of the case where an amorphous silicide film is deposited on the polycrystalline silicon film, but the present invention is similarly applicable also to the case where an amorphous silicide film is deposited on an amorphous silicon film and thermal treatment induces both of them to crystallize.

In First Embodiment, the polycrystalline silicon film is completely flattened by the CMP process, but occurrence of a crack is suppressed even if the above sharp recess on the surface of a silicon film is smoothed so as to make the surface smooth by the CMP process.

In the embodiments of the present invention, the cases of titanium silicide were described. However, the present invention is similarly applicable to the formation of a silicide film of a high melting point metal except titanium, such as, e.g. W, Co, Ni or Ta.

Furthermore, the present invention is similarly applicable also to the formation of a polymetal structure made by stacking a high melting-point metal film on a nitride film of a high melting-point metal such as WN film or TaN film. Here, high melting point metals include W, Ta, Co and Ti.

The present invention is not limited to any of First to Fourth Embodiments and evidently, any embodiment may be modified appropriately within the technical ideas of the present invention.

According to the present invention, as mentioned above, sharp recesses generated on the surface of the silicon film are removed, then an amorphous high melting point metal silicide film or a high melting point metal film via a nitride film of a high melting-point metal is formed on the surface of the silicon film in the formation of wiring such as gate electrode of a polycide structure or a polymetal structure using a high melting-point metal. And, this amorphous high melting-point metal silicide film or the like is crystallized and both the polycrystalline silicon film and the high melting-point metal silicide film are patterned to form the gate electrode of a MOS transistor.

Removal of such sharp recesses alleviates the tensile stress imposed on a high melting-metal or its silicide film by the thermal treatment for the crystallization and eliminates the occurrence any crack as was frequent for the related art.

In this manner, in addition to facilitating the formation of highly reliable low resistance minute gate electrode wiring and enhancing the miniaturization and the function promotion of a semiconductor device, the present invention improves the mass production yield of semiconductor devices.

What is claimed is:

1. A method of manufacturing a semiconductor device for forming a wiring layer of said semiconductor device comprising the steps of:
forming a silicon film on a surface of an underlying insulating layer, said underlying insulating layer having a concave portion;
flattening a surface of a high melting-point metal silicide film by a flattening treatment;
forming a high melting-point metal silicide film of amorphous state or forming a high melting-point metal film of amorphous via a nitride film of a high melting-point metal on the flattened surface of said silicon film; and
crystallizing said high melting-point metal silicide film or said high melting-point metal film by a heat treatment.

2. The method of manufacturing a semiconductor device of claim 1, wherein said flattening treatment is a chemical mechanical polishing treatment applied to said surf ace of said silicon film.

3. The method of manufacturing a semiconductor device of claim 1, wherein said flattening treatment is a reactive ion etching treatment removing a predetermined depth of said surface of a said silicon film.

4. The method of manufacturing a semiconductor device of claim 1, wherein said flattening treatment includes a first step of forming a thermal oxide film on said surface on said silicon surface by thermal oxidizing and removing said thermal oxide film.

5. The method of manufacturing a semiconductor device of claim 4, wherein said thermal oxidizing is a rapid thermal oxidizing.

6. The method of manufacturing a semiconductor device of claim 4, wherein said thermal oxidizing is a heat treatment under a mixing gas atmosphere of chloride of phosphoric acid (POCl₃) and oxygen (O₂).

7. The method of manufacturing a semiconductor device of claim 1, wherein said silicon film is a polycrystalline silicon film or an amorphous silicon film.

8. The method of manufacturing a semiconductor device of claim 7, wherein a n impurity to determine N type or P type is introduced into said silicon film when said silicon film is deposited on said sur f ace of said underlying insulating layer.

9. The method of manufacturing a semiconductor device of claim 1, wherein said melting-point metal silicide film is a titanium silicide film, a tungsten silicide film or cobalt silicide film.

10. The method of manufacturing a semiconductor device of claim 1, wherein said melting-point metal film is a titanium film, a tungsten film or cobalt film.

11. The method of manufacturing a semiconductor device of claim 1, after crystallizing said high melting-point metal silicide film or said high melting-point metal film; further comprising a step of patterning said high melting-point metal silicide film and said silicon film or patterning said high melting-point metal film, said nitride film of said high melting-point metal and said silicon film to form a gate electrode wiring of an insulated gate field effect transistor.

12. The method of manufacturing a semiconductor device of claim 11, said underlying insulating layer having concave portion is an element-isolating layer defining an element-forming region in which said insulated gate field effect transistor is formed.

13. A method of manufacturing a semiconductor device for forming a wiring layer of said semiconductor device comprising the steps of:
forming a silicon film on a surface of an underlying insulating layer, said underlying insulating layer having a concave portion;
forming a high melting-point metal silicide film of amorphous state or forming a high melting-point metal film of amorphous via a nitride film of a high melting-point metal on a surface of said silicon film; and thereafter
crystallizing said high melting-point metal silicide film or said high melting-point metal film by a heat treatment.

14. The method of manufacturing a semiconductor device of claim 13, wherein said silicon film is a polycrystalline silicon film or an amorphous silicon film.

15. The method of manufacturing a semiconductor device of claim 14, wherein an impurity to determine N type or P type is introduced into said silicon film when said silicon film is deposited on said surface of said underlying insulating layer.

16. The method of manufacturing a semiconductor device of claim 13 wherein said melting-point metal silicide film is a titanium silicide film, a tungsten silicide film or cobalt silicide film.

17. The method of manufacturing a semiconductor device of claim 13 wherein said melting-point metal film is a titanium film, a tungsten film or cobalt film.

18. The method of manufacturing a semiconductor device of claim 13, after crystallizing said high melting-point metal silicide film or said high melting-point metal film; further comprising a step of patterning said high melting-point metal silicide film and said silicon film or patterning said high melting-point metal film, said nitride film of said high melting-point metal and said silicon film to form a gate electrode wiring of an insulated gate field effect transistor.

19. The method of manufacturing a semiconductor device of claim 18, said underlying insulating layer having concave portion is an element-isolating layer defining an element-forming region in which said insulated gate field effect transistor is formed.
